(19) United States
(12) Patent Application Publication
(10) Pub. No.: US 2008/0157378 A1
(43) Pub. Date: Jul. 3, 2008

(54) SEMICONDUCTOR DEVICE, AND METHOD OF MANUFACTURING SAME

(75) Inventor: Min Hyung LEE, Cheongju-si (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: Dongbu HiTek Col, Ltd., Seoul (KR)

(21) Appl. No.: 11/933,901

(22) Filed: Nov. 1, 2007

(30) Foreign Application Priority Data
Dec. 29, 2006 (KR) 10-2006-0137558

(51) Int. Cl. H01L 23/52; H01L 21/4763

(52) U.S. Cl. 257/751; 438/643; 257/E23.141; 257/E21.495

(57) ABSTRACT

A semiconductor device, and method for manufacturing a device with selective copper plating in a deep via. The method comprises etching a plurality of deep trenches in the surface of wafer, sequentially forming an insulating layer, a copper anti-diffusion layer, a metal layer, and a copper seed layer over the surface and deep trenches of the wafer, performing a first planarization process in order to remove the copper seed layer on the surface of wafer while retaining the copper seed layer in the deep trenches of the wafer, and forming a plurality of via patterns by copper plating the copper seed layer remaining in the deep trenches of the wafer.

### CROSS-REFERENCE TO RELATED APPLICATIONS

This application claims the benefit of Korean Patent Application No. 10-2006-0137558, filed on Dec. 29, 2006, which is hereby incorporated by reference in its entirety.

### BACKGROUND OF THE INVENTION

1. Field of the Invention

The present invention relates to a semiconductor device. More particularly, the present invention relates to a method of manufacturing a semiconductor device with selective copper plating in a deep via.

2. Discussion of the Related Art

As our society has become more information-oriented, various technologies have arose, including the internet and other types of communication technology. Along with these technologies, the number of devices requiring of a semiconductor device is constantly expanding.

Semiconductor devices have been used for a wide variety of products requiring electricity, from mobile products such as cellular phones, PDAs, etc., to traditional home appliances such as TVs, audio devices, etc.

Because of the wide number of applications using semiconductor devices, a variety of semiconductor devices with various functions that meet the specialized demands of the various products are needed. In particular, there is increasing a demand for a small, multifunctional, and high-speed semiconductor device that may be used in a mobile product such as a cellular phone.

One difficulty in developing such semiconductor devices, however, is that it is increasingly difficult for the fine circuit manufacturing technology of the semiconductor device industry to create a specialized product due to the length of time required to develop the devices, the enormous facility investment, and rapid increase in processing and manufacturing costs.

One solution to these problems is a so-called system in package, or SIP, which makes one package by stacking the same or various kinds of semiconductor devices vertically in a via pattern at the chip or wafer level and circuitally interconnecting the wafers or chips. Unlike existing single chip packages, the SIPs vertically stack the chips so that the same kind of chips are stacked in order to raise storage density or in order to facilitate the storage of information and logic functions in a single package with composite functions. One advantage of such systems, is that it is possible to make the final product that is compact, lightweight, and multifunctional.

One technology for manufacturing the SIP is to form a via pattern using a method known in the art, as shown in FIG. 1. Using this method, the via pattern is first formed by vertically stacking chips or wafers and interconnecting them by the via pattern. Next, a deep trench is formed on the completed wafer 100 by etching exposed wafer areas using a plurality of photoresist patterns (not shown) as etching masks. Next, the photoresist patterns are removed, and a via trench is preferably formed at a depth which does not penetrate through the entire wafer 100.

Next, the trench is filed by forming an insulating layer 110, a copper barrier layer 120, and a copper seed layer, sequentially, over the wafer 110. Next, a copper metal layer 130 is formed on the copper seed layer using a predetermined electroplating method. Next, a chemical mechanical polishing (CMP) process is performed so as to remove any copper metal layer 130 and the copper barrier layer 120 deposited on the outside of the via, thus forming the deep via.

One difficulty of using the method described above, however, is that the method forms a deep via with the depth of 100 μm or more. Therefore, the amount of copper plating is large, meaning that the amount of copper removed during the CMP process is large, resulting in wasted materials and increased costs.

### BRIEF SUMMARY OF THE INVENTION

The present invention proposes to solve the forgoing problems by providing a method of manufacturing a semiconductor device with selective copper plating in a deep via using a deep via gap-fill process.

One aspect of the invention is a method of manufacturing a semiconductor device comprising forming a plurality of deep trenches by etching the surface of a wafer, sequentially forming an insulating layer, a copper anti-diffusion layer, a metal layer, and a copper seed layer over the surface and deep trenches of the wafer, performing a first planarization process in order to remove the copper seed layer from the surface of the wafer while retaining the copper seed layer in the deep trenches of the wafer, and forming a plurality of via patterns using a copper plating process on the copper seed layer remaining in deep trenches of the wafer. A second aspect of the invention is a semiconductor device comprising a plurality of deep trenches formed in a surface of a wafer using an etching process, an insulating layer, a copper anti-diffusion layer, a metal layer, and a copper seed layer formed sequentially over the deep trenches and surface of the wafer, and a plurality of copper via patterns formed using copper plating process on the copper seed layer, wherein the copper seed layer is removed from the surface of the wafer while being retained in the deep trenches of the wafer before the copper plating process is performed, such that the copper via pattern forms only over the deep trenches of the wafer.

### BRIEF DESCRIPTION OF THE DRAWINGS

The accompanying drawings are included to provide a further understanding of the invention and are incorporated in and constitute a part of this application. The drawings illustrate embodiment(s) of the invention and together with the description serve to explain the purpose and scope of the invention. In the drawings:

FIG. 1 is a cross-sectional view for illustrating a method of manufacturing a semiconductor device known in the related art; and

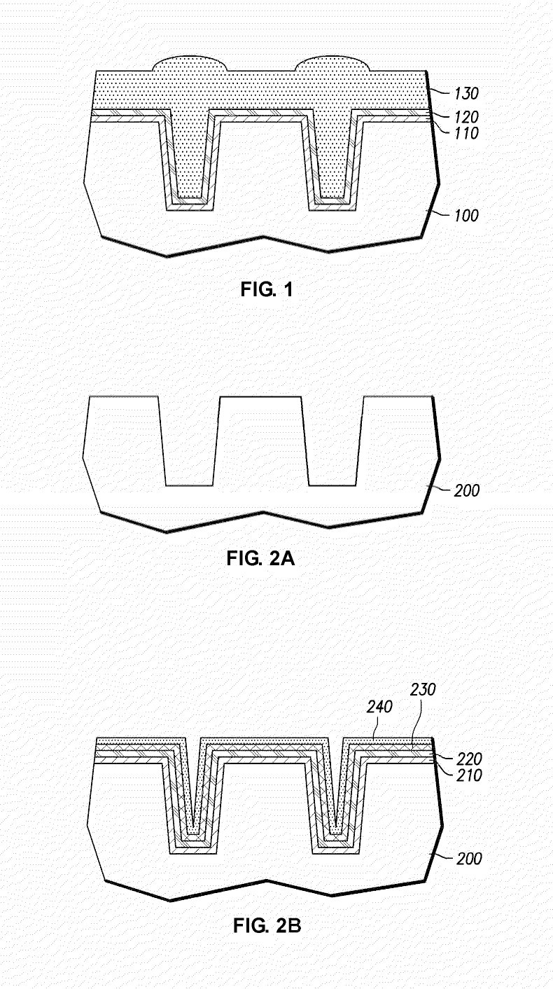

FIGS. 2A-2E are cross-sectional views for illustrating a method of manufacturing a semiconductor device according to embodiments of the present invention.

### DETAILED DESCRIPTION OF THE INVENTION

Hereinafter, a method of manufacturing a semiconductor device according to embodiments of the present invention will be described in detail with reference to the accompanying drawings.

The technical contents well-known to the technical field of the present invention which are not directly related to the present invention will be omitted herein. This is to focus on novel aspects of the present invention without obscuring the meaning and scope of the invention.

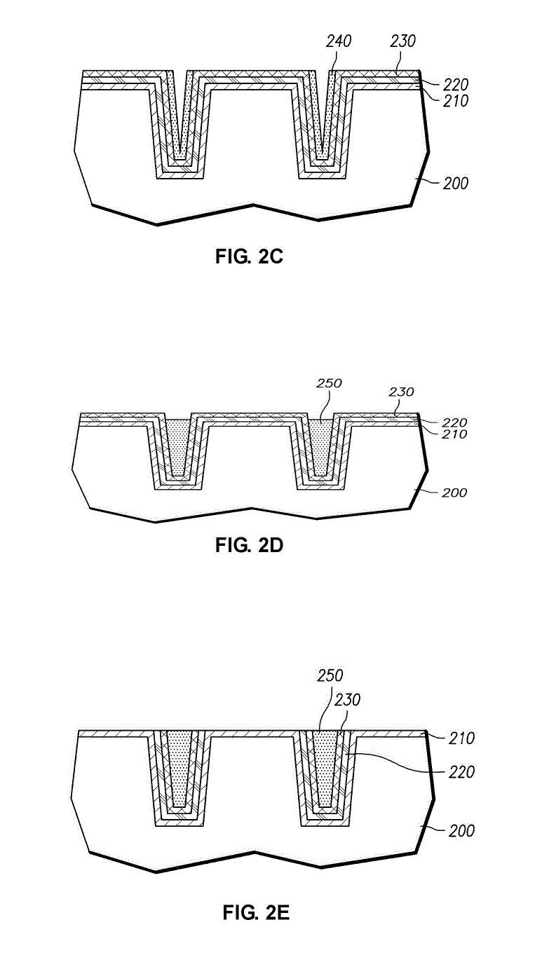

FIGS. 2a to 2e are cross-sectional views illustrating a method of manufacturing a semiconductor device according to embodiments of the present invention.

As shown in FIG. 2a, a plurality of deep trenches are formed on a wafer 200 in order expose a via pattern forming area on the wafer 200. In order to form the trench, the via pattern forming area is etched using a plurality of photoresist patterns (not shown). Typically during this process the wafer 200 is prepared and a photoresist film is then coated on the wafer 200.

Next, a plurality of photoresist patterns (not shown) are formed so as to expose a via hole forming area by exposing and developing the photoresist film. Thereafter, the plurality of deep trenches are formed by etching the exposed wafer area using the photoresist pattern as an etching mask.

Preferably, the deep trench is formed at a depth that does not penetrate through the wafer 200, for example, at a depth of 20 to 100 μm.

Next, as shown in FIG. 2b, an insulating layer 210, a copper anti-diffusion layer 220, a metal layer, and a copper seed layer 240 are formed, sequentially, over the surface of the wafer 200 and deep trenches.

In this example, the insulating layer 210 is formed using a chemical vapor deposition (CVD) method. In particular, the insulating layer 210 is formed from a material selected from the group of SiO₂, SiN, SiON and thermal oxide and is preferably formed at a thickness of between 10 and 50000 Å. After the insulating layer 210 is formed, there is a groove in the area in which the trench is formed.

Next, the copper anti-diffusion film 220 is formed on the upper surface of the insulating layer 210 using a PVD or an ALD method. The copper anti-diffusion layer 220 is formed using any material selected from the group of Ta, TaN, Ti, TiN, TaSiN and TiSiN and is preferably formed at a thickness of between 10 and 10000 Å. After the copper anti-diffusion layer 220 is formed, there is a groove in the area in which the trench is formed.

Next, a metal layer 230 is preferably formed at a thickness of between 100 to 50000 Å using aluminum (Al). After the metal film 230 is formed, there is the groove in the area in which the trench is formed.

Next, a copper seed film 240 is preferably formed at a thickness of between 100 and 10000 Å. After the copper seed film 240 is formed, there is the groove in a V letter form in the area in which the trench is formed.

As described above, when the insulating layer 210, the copper anti-diffusion layer 220, the metal layer 230, and the copper seed layer 240 are sequentially formed in the inside of the trench, the thickness of each film is controlled so that the inside of the trench is not completely filled.

Herein, a layer of oxidized metal can form on the surface of the metal layer 230 prior to forming the copper seed layer 240. Therefore a dry etch may be performed using a gas including Ar and H₂ in order to remove the oxidized metal. The dry etch may be a plasma dry etch.

Next, a first planarization process is performed on the upper surface of the wafer 200 using a CMP method. More specifically, the first planarization process may be performed on the copper seed layer 240 using a CMP method. Thus, as shown in FIG. 2c, the first planarization process may continue until the copper seed layer is removed from the surface of the wafer and the metal layer 230 of aluminum is exposed on the upper surface of the wafer 200. At the same time, the copper seed layer 240 is permitted to remain on the surface of the metal layer 230 in the trench area.

Next, as shown in FIG. 2d, a copper plating process is performed on the copper seed layer 240 in the inner wall of the trench, in order to form a plurality of deep via patterns 250. At this time, the metal layer 230 of aluminum exposed during the first planarization process on the surface of the wafer 200 remains exposed. During this time, the aluminum is subject to oxidation, forming alumina (Al₂O₃) on the surface of the metal layer 230

Advantageously, the alumina suppresses the copper plating, and the current flowing during the copper plating process flows into the area where the alumina is not formed. Thus, the portion of aluminum formed in the groove of the trench area where the copper seed film 240 remains allows the copper plating process to copper plate the surface of the trench area.

Accordingly, the copper plating process selectively forms a copper layer on inside of the deep via pattern 250. Advantageously, this results in a reduced amount of copper plating solution consumed in the copper plating process, making it possible to reduce costs.

Next, as shown in FIG. 2e, a second planarization process may be performed on the surface of the semiconductor in an area other than the via pattern 250. That is, the copper anti-diffusion layer 220 and the metal layer 230 may be removed from the surface of the wafer 200 using a wet etch. This second planarization process may be performed until the insulating layer 210 is exposed on the upper surface of the wafer 200.

The second planarization process can be performed using the same CMP method as the first planarization process.

Also, as mentioned above, the selective copper plating results in copper being formed only in the inside of the deep via so that the amount of copper removed during the second planarization process may be minimized. Therefore, the CMP process can be simplified and more cost effective.

The example of the present invention described above with reference to the drawings is meant to be illustrative only, and is not intended limit the technical scope and meaning of the present invention. Thus, it is intended that the present invention covers the modifications and variations of this invention that come within the scope of the appended claims and their equivalents.

Using embodiments of the present invention described above, selective copper plating may be formed in a deep via for System in Package semiconductors, such that the amount of copper removed in the semiconductor manufacturing process can be minimized, making it possible to considerably reduce costs.

What is claimed is:

1. A method of manufacturing a semiconductor device comprising:
forming a plurality of deep trenches in a surface of a wafer using an etching process;
sequentially forming an insulating layer, a copper anti-diffusion layer, a metal layer, and a copper seed layer over the deep trenches and surface of the wafer;
performing a first planarization process on the copper seed layer in order to remove the copper seed layer from the surface of the wafer while retaining the copper seed layer in the deep trenches of the wafer; and
forming a plurality of via patterns by performing a copper plating process on the copper seed layer remaining in the deep trenches of the wafer.

2. The method according to claim 1, further comprising performing a second planarization process on the copper anti-diffusion layer and the metal layer on the wafer until the insulating layer is exposed on the surface of the wafer.

3. The method according to claim 1, wherein the insulating layer is formed using a CVD process with any material from the group of SiO₂, SiN, SiON, and thermal oxide.

4. The method according to claim 1, wherein the copper anti-diffusion layer is formed using a PVD or an ALD process.

5. The method according to claim 1, wherein the copper ant-diffusion layer is formed using a PVD or an ALD process with any material from the group of Ta, TaN, Ti, TiN, TaSiN and TiSiN.

6. The method according to claim 1, wherein the copper anti-diffusion layer is formed with a thickness between 10 and 10000 Å.

7. The method according to claim 1, wherein the metal layer is formed of aluminum (Al).

8. The method according to claim 1, wherein the metal layer is formed of aluminum with a thickness between 100 and 50000 Å.

9. The method according to claim 1, wherein sequentially forming the insulating layer, the copper anti-diffusion layer, the metal layer, and the copper seed layer comprises performing a plasma dry etch process prior to forming the copper seed layer, wherein the plasma dry etch process uses a gas including Ar and H₂ in order to remove any native oxide formed in the metal layer.

10. The method according to claim 1, wherein the copper seed layer is formed with a thickness of between 100 and 10000 Å.

11. A semiconductor device comprising:
a plurality of deep trenches formed in a surface of a wafer using an etching process;
an insulating layer, a copper anti-diffusion layer, a metal layer, and a copper seed layer formed sequentially over the deep trenches and surface of the wafer; and
a plurality of copper via patterns formed using copper plating process on the copper seed layer;
wherein the copper seed layer is removed from the surface of the wafer while being retained in the deep trenches of the wafer before the copper plating process is performed, such that the copper via pattern forms only over the deep trenches of the wafer.

12. The device according to claim 11, wherein the copper anti-diffusion layer and metal layer are removed from the surface of the wafer while being retained in the deep trenches of the wafer such that the insulating layer is exposed on the surface of the wafer.

13. The device according to claim 11, wherein the insulating layer is any material from the group of SiO₂, SiN, SiON, and thermal oxide.

14. The device according to claim 11, wherein the insulating layer has a thickness of between 10 and 50000 Å.

15. The device according to claim 11, wherein the copper anti-diffusion layer is formed using a PVD or an ALD process.

16. The device according to claim 11, wherein the copper ant-diffusion layer is any material from the group of Ta, TaN, Ti, TiN, TaSiN and TiSiN.

17. The device according to claim 11, wherein the copper anti-diffusion layer is formed with a thickness between 10 and 10000 Å.

18. The device according to claim 11, wherein the metal layer is aluminum (Al).

19. The device according to claim 11, wherein the metal layer is aluminum with a thickness between 100 and 50000 Å.

20. The device according to claim 11, wherein the copper seed layer is formed with a thickness of between 100 and 10000 Å.
